(19) United States
(12) Patent Application Publication
(10) Pub. No.: US 2026/0033326 A1
(43) Pub. Date: Jan. 29, 2026

(54) MICROELECTRONIC DEVICES AND RELATED MEMORY DEVICES AND ELECTRONIC SYSTEMS

(71) Applicant: Micron Technology, Inc., Boise, ID (US)

(72) Inventor: Agostino Macerola, San Benedetto dei Marsi (IT)

(21) Appl. No.: 19/254,805

(22) Filed: Jun. 30, 2025

Related U.S. Application Data
(60) Provisional application No. 63/676,772, filed on Jul. 29, 2024.

(51) Int. Cl. H01L 23/522; H01L 23/00; H01L 23/528; H01L 25/18; H10B 41/20; H10B 41/35; H10B 43/20; H10B 43/35; H10B 80/00; H10D 80/30

(52) U.S. Cl. CPC H01L 23/5227; H01L 23/5283; H01L 24/08; H01L 25/18; H10B 41/20; H10B 41/35; H10B 43/20; H10B 43/35; H10B 80/00; H10D 80/30; H01L 2224/08145; H01L 2924/1431; H01L 2924/1438

(57) ABSTRACT

A microelectronic device includes a memory array region, an interconnect region, and a control logic region. The memory array region includes a stack structure including tiers each including conductive material and insulative material vertically neighboring the conductive material and conductive routing overlying the stack structure. The interconnect region underlies the memory array region and includes connected bond pads. The control logic region underlies the interconnect region and comprises control logic devices to effectuate control operations for the microelectronic device. The microelectronic device may also include a conductive loop assembly extending, in a looped path, through each of the memory array region, the interconnect region, and the control logic region.

### CROSS-REFERENCE TO RELATED APPLICATIONS

This application claims the benefit under 35 U.S.C. § 119 (e) of U.S. Provisional Patent Application Ser. No. 63/676,772, filed Jul. 29, 2024, the disclosure of which is hereby incorporated herein in its entirety by this reference.

### TECHNICAL FIELD

The disclosure, in various embodiments, relates generally to the field of microelectronic device design and fabrication. More specifically, the disclosure relates to microelectronic devices including a control logic region overlying a memory array region, and to relative memory devices and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes vertical memory strings extending through openings in one or more decks (e.g., stack structures) including tiers of conductive structures and dielectric materials. Each vertical memory string may include at least one select device coupled in series to a serial combination of vertically stacked memory cells. Such a configuration permits a greater number of switching devices (e.g., transistors) to be located in a unit of die area (i.e., length and width of active surface consumed) by building the array upwards (e.g., vertically) on a die, as compared to structures with conventional planar (e.g., two-dimensional) arrangements of transistors.

Control logic devices within a base control logic structure underlying a memory array of a memory device (e.g., a non-volatile memory device) have been used to control operations (e.g., access operations, read operations, write operations) on the memory cells of the memory device. An assembly of the control logic devices may be provided in electrical communication with the memory cells of the memory array by way of routing and interconnect structures. However, processing conditions (e.g., temperatures, pressures, materials) for the formation of the memory array over the base control logic structure can limit the configurations and performance of the control logic devices within the base control logic structure. In addition, the quantities, dimensions, and arrangements of the different control logic devices employed within the base control logic structure can also undesirably impede reductions to the size (e.g., horizontal footprint) of a memory device, and/or improvements in the performance (e.g., faster memory cell ON/OFF speed, lower threshold switching voltage requirements, faster data transfer rates, lower power consumption) of the memory device.

### BRIEF DESCRIPTION OF THE DRAWINGS

FIG. 1 is a simplified, vertical cross-sectional view of a microelectronic device, in accordance with embodiments of the disclosure.

FIG. 2A is a simplified, vertical side view of a conductive loop structure of the microelectronic device shown in FIG. 1, according to embodiments of the disclosure.

FIG. 2B is a simplified, perspective view of the conductive loop structure shown in FIG. 2A.

FIG. 3 is a vertical cross-sectional view of a conductive loop structure array having a plurality of conductive loop structures arranged in series, according to embodiments of the disclosure.

FIG. 4 shows a connection diagram illustrating connections for a wiring pattern for each conductive loop structure of the conductive loop structure array shown in FIG. 3, according to embodiments of the disclosure.

FIG. 5A shows a connection diagram for an interleaved conductive loop structure array that includes a first set of conductive loop structures interleaved between a second set of conductive loop structures, according to embodiments of the disclosure. FIG. 5B shows a diagram demonstrating a magnetic flux B generated by loops of the first set of conductive loop structures combined with a magnetic flux B generated by loops of the second set of conductive loop structures, according to embodiments of the disclosure. FIG. 5C shows a transformer diagram. The first set of conductive loop structures is used to induce a voltage in the second set of conductive loop structures, according to embodiments of the disclosure.

FIG. 6 shows a simplified, vertical side view of a configuration including an outer conductive loop structure concentrically surrounding the conductive loop structure shown in FIGS. 2A and 2B, according to embodiments of the disclosure.

FIGS. 7A and 7B show different simplified vertical side views, in directions orthogonal to one another, of a conductive loop structure (FIG. 7A) and a conductive loop structure array (FIG. 7B) surrounding a ferromagnetic material, according to embodiments of the disclosure.

FIG. 8 is a simplified, schematic block diagram of an electronic system, in accordance with an embodiment of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device, such as 3D NAND Flash memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” and “horizontal,” are in reference to a major plane of a structure and are not necessarily defined by earth's gravitational field. A “horizontal” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for case of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “underlying” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiₓCO_{y}H_{z})), and at least one dielectric carboxynitride material (e.g., a silicon carboxynitride (SiOₓC_{z}N_{y})). In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials. In addition, each of a “semiconductor structure” and a “semiconductive structure” means and includes a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓ N_{y}, SiOₓC_{y}, SiOₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, “ferromagnetic material” means and includes a material exhibiting strong magnetism, allowing the material to form permanent magnets or to be attracted by magnets. Ferromagnetic materials include, but are not limited to, one or more of iron (Fe), Cobalt (Co), Nickel (Ni), Gadolinium (Gd), Neodymium (Nd), Dysprosium (Dy), Permalloy, Wairakite (Ca8(Al₁₆Si₃₂O₉₆)·16H₂O), Magnetite (Fe₃O₄), and the like.

Unless the context indicates otherwise, the materials described herein may be formed by any suitable technique including, but not limited to, spin coating, blanket coating, chemical vapor deposition (“CVD”), atomic layer deposition (“ALD”), plasma enhanced ALD, physical vapor deposition (“PVD”) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization, or other known methods.

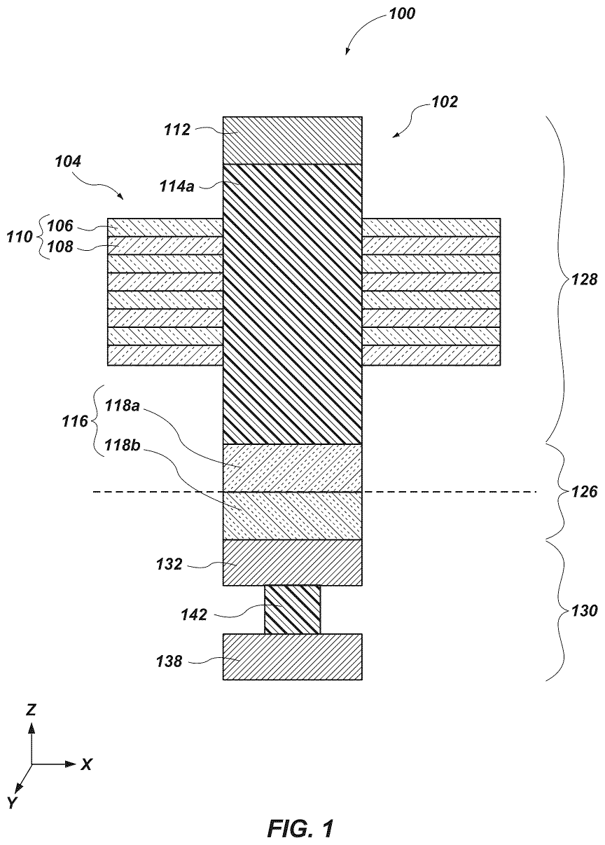

FIG. 1 is a simplified, vertical cross-sectional view of a microelectronic device 100 (e.g., a memory device, such as a 3D NAND Flash memory device), in accordance with embodiments of the disclosure. With the description provided below, it will be readily apparent to one of ordinary skill in the art that microelectronic devices described herein may be included in various relatively larger devices and various electronic systems.

The microelectronic device 100 may include a memory array region 128, an interconnect region 126, and a control logic region 130. As shown in FIG. 1, the interconnect region 126 may vertically underlie (e.g., in the Z-direction) and be in electrical communication with the memory array region 128, and the control logic region 130 may vertically underlie and be in electrical communication with the interconnect region 126. The interconnect region 126 may be vertically interposed between and in electrical communication with the memory array region 128 and the control logic region 130. The microelectronic device 100 may also include a conductive loop structure 102 (also referred to herein as a “conductive loop assembly”) vertically extending from the memory array region 128 through the interconnect region 126 to the control logic region 130. The microelectronic device 100 may be formed, at least in part, from a first microelectronic device structure attached (e.g., bonded) to a second microelectronic device structure. The first microelectronic device structure may include at least the memory array region 128 and a portion (e.g., an upper portion) of the interconnect region 126. The second microelectronic device structure may include at least the control logic region 130 and an additional portion (e.g., a lower portion) of the interconnect region 126. In some embodiments, the first microelectronic device structure (including the components of the memory array region 128 and the interconnect region 126) and the second microelectronic device structure (including the components of the control logic region 130 and the additional portion of the interconnect region 126) may be formed separately from one another, and then may be attached to on another at an interface depicted by way of a dashed line in FIG. 1. The second microelectronic device structure may, for example, be bonded to the first microelectronic device structure through a combination of dielectric-to-dielectric bonding and metal-to-metal bonding, as described in further detail below. The second microelectronic device structure may be attached to the first microelectronic device structure with or without a bond line. Additional components of the microelectronic device 100, such as, without limitation, some components of the control logic region 130, may be formed subsequent to the attachment of the second microelectronic device structure to the first microelectronic device structure, as also described in further detail below.

Still referring to FIG. 1, the memory array region 128 may include a conductive routing 112 stack structure 104 vertically interposed. The stack structure may be vertically interposed between conductive routing tiers. One of the conductive routing tiers may include digit line structures coupled to strings of memory cells (described in further detail below) within the stack structure 104; and the an other of the conductive routing tiers may include a source structure coupled to strings of memory cells within the stack structure 104. The conductive routing tier including the digit lines structures is vertically offset (e.g., in the Z-direction) from the stack structure 104, and may include additional features (e.g., additional conductive structures, such as routing structures) coupled to additional features (e.g., pillar structures, filled vias) within the boundaries (e.g., vertical boundaries, horizontal boundaries) of stack structure 104 and further features (e.g., contact structures) within the boundaries (e.g., vertical boundaries, horizontal boundaries) of the interconnect region 126 of the microelectronic device 100. The conductive routing tier including the source structure may also be vertically offset from the stack structure 104 and may include other features (e.g., other conductive features, such as other routing structures) coupled to the additional features (e.g., pillar structures, filled vias) within the boundaries (e.g., vertical boundaries, horizontal boundaries) of the stack structure 104. As shown in FIG. 1, in some embodiments, some conductive routing 112 is formed to vertically overlie the stack structure 104.

The stack structure 104 of the memory array region 128 includes a vertically alternating (e.g., in the Z-direction) sequence of conductive structures 108 and insulative structures 106 arranged in tiers 110. Each of the tiers 110 of the stack structure 104 may include at least one of the conductive structures 108 vertically neighboring at least one of the insulative structures 106. In some embodiments, the conductive structures 108 are formed of and include tungsten (W) and the insulative structures 106 are formed of and include silicon dioxide (SiO₂). The conductive structures 108 and insulative structures 106 of the tiers 110 of the stack structure 104 may each individually be substantially planar, and may each individually exhibit a desired thickness.

The memory array region 128 may include other structures or components in addition to the stack structure 104 for facilitating operation of the microelectronic device 100. For example, the memory array region 128 may further include cell pillar structures horizontally overlapping and vertically extending through the stack structure. The cell pillar structures may individually be formed of and include a stack of materials facilitating the use of the cell pillar structures to form strings of memory cells vertically extending through the stack structure 104.

Intersections of the cell pillar structures and the conductive structures 108 of the tiers 110 of the stack structure 104 may define vertically extending strings of memory cells coupled in series with one another within the memory array region 128 of the microelectronic device 100. In some embodiments, the memory cells formed at the intersections of the conductive structures 108 and the cell pillar structures within each the tiers 110 of the stack structure 104 comprise so-called “MONOS” (metal-oxide-nitride-oxide-semiconductor) memory cells. In additional embodiments, the memory cells comprise so-called “TANOS” (tantalum nitride-aluminum oxide-nitride-oxide-semiconductor) memory cells, or so-called “BETANOS” (band/barrier engineered TANOS) memory cells, each of which are subsets of MONOS memory cells. In further embodiments, the memory cells comprise so-called “floating gate” memory cells including floating gates (e.g., metallic floating gates) as charge storage structures. The floating gates may horizontally intervene between central structures of the cell pillar structures and the conductive structures 108 of the different tiers 110 of the stack structure 104.

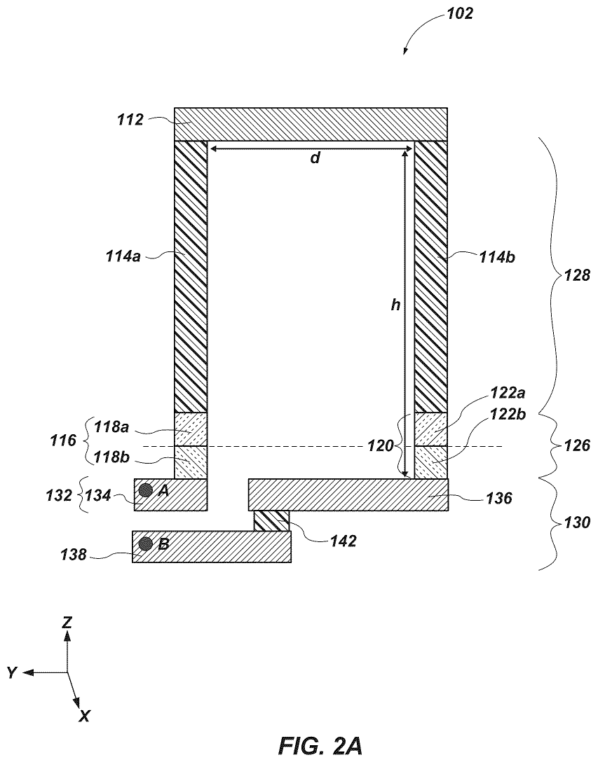

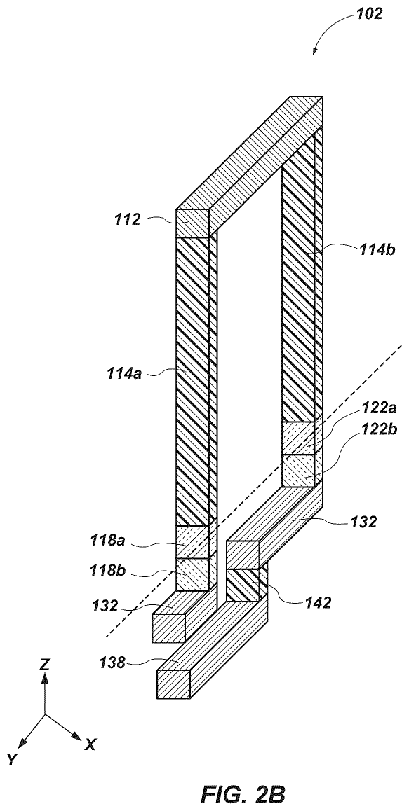

With continued reference to FIG. 1, the interconnect region 126 of the microelectronic device 100 may couple features of the control logic region 130 to features of the memory array region 128. The interconnect region 126 may include first connected bond pads 116 and second connected bond pads 120 (FIGS. 2A and 2B), without limitation. An individual first connected bond pad 116 may include a bond pad 118a overlying and bonded (e.g., metal-to-metal bonded) to a bond pad 118b. Similarly, an individual second connected bond pad 120 (FIGS. 2A and 2B) may include a bond pad 122a (FIGS. 2A and 2B) overlying and bonded (e.g., metal-to-metal bonded) to a bond pad 118b (FIGS. 2A and 2B). The first connected bond pads 116 and the second connected bond pads 120 may couple to one or more structures of the memory array region 128 to one or more structures and/or devices of the control logic region 130.

The first connected bond pads 116 and the second connected bond pads 120 (FIGS. 2A and 2B) may be formed of and/or include conductive material. By way of non-limiting example, the first connected bond pads 116 and the second connected bond pads 120 may be formed of and include one or more of at least one metal, at least one alloy, and at least one conductive metal-containing material (e.g., a conductive metal nitride, a conductive metal silicide, a conductive metal carbide, a conductive metal oxide). In some embodiments, the first contact structures first connected bond pads 116 and/or the second connected bond pads 120 are formed of and include Cu. In some embodiments, the first connected bond pads 116 and/or the second connected bond pads 120 are formed of and include W.

The microelectronic device 100 may also include one or more semiconductor structures. For example, the microelectronic device 100 may include a first base semiconductor structure overlying the memory array region 128 and a second base semiconductor structure underlying the control logic region 130.

FIG. 2A is a simplified, vertical side view of the conductive loop structure 102 of the microelectronic device 100 previously described with reference to FIG. 1, according to embodiments of the disclosure. FIG. 2B is simplified, perspective view of the conductive loop structure 102 shown in FIG. 2A.

Referring to FIGS. 1, 2A, and 2B together, the conductive loop structure 102 may include the conductive routing 112, a first conductive contact structure 114a and a second conductive contact structure 114b, the first connected bond pad 116, the second connected bond pad 120, a first material 132, a third contact structure 142, and a second material 138. The first conductive contact structure 114a and the second conductive contact structure 114b vertically extend from the conductive routing 112 to the interconnect region 126, specifically to the first connected bond pad 116 and the second connected bond pad 120, respectively, of the interconnect region 126. The bond pad 118b of the first connected bond pad 116 and the bond pad 122b of the second connected bond pad 120 may be coupled to one or more portions of the first material 132. For example, a bond pad 118b of the first connected bond pad 116 may be coupled to a first portion 134 of the first material 132, and the bond pad 122b of the second connected bond pad 120 may be coupled to a second portion 136 of the first material 132. The first portion 134 and the second portion 136 of the first material 132 may be positioned at substantially the same vertical elevation (e.g., in the Z-direction) as one another within the microelectronic device 100, but are horizontally separate (e.g., in the X-direction and the Y-direction) from another within of the microelectronic device 100. In some embodiments, insulative material may be disposed between the first portion 134 and the second portion 136 of the first material 132.

The first material 132 and the second material 138 may be vertically offset (e.g., in the Z-direction) from one another. In addition, the third contact structure 142 may vertically extend from and between the second portion 136 of the first material 132 to the second material 138. The second material 138 may vertically underlie the first material 132. As collectively shown in FIGS. 2A and 2B, the second material 138 may at least partially horizontally overlap (e.g., in the X-direction, in the Y-direction) the first portion 134 of the first material 132.

As will be described in further detail below, the configuration of the microelectronic device 100, including the arrangement of the different regions (e.g., the memory array region 128, the interconnect region 126, and the control logic region 130) thereof forming the conductive loop structure 102 may facilitate enhanced signal transmission speed and improved signal integrity during use and operation of the microelectronic device 100 as compared to conventional microelectronic device configurations. For example, by providing a current of electricity to the first portion 134 of the first material 132, the current may travel through the first portion 134, the first connected bond pad 116, the first conductive contact structure 114a, the conductive routing 112, the second conductive contact structure 114b, the second connected bond pad 120, the second portion 136 of the first material 132, the third contact structure 142, and the second material 138 such that the conductive loop structure 102 acts as an induction loop. Magnetic flux created by the induction loop may then aid electrons flowing in the direction of the magnetic flux, which may aid in the performance of one or more functions of the microelectronic device 100 (e.g., access operations, read operations, write operations).

The first conductive contact structure 114a and the second conductive contact structure 114b may horizontally overlap and vertically extend through or beside (e.g., on one or more horizontal sides of) the stack structure 104. The first conductive contact structure 114a and the second conductive contact structure 114b may be configured and positioned to electrically connect one or more components of the microelectronic device 100 vertically overlying the stack structure (e.g., the conductive routing 112) with one or more other components of the microelectronic device 100 vertically underlying the stack structure 104 (e.g., components of the interconnect region 126 and/or components or devices of the control logic region 130). The first conductive contact structure 114a and the second conductive contact structure 114b may individually be formed of and include conductive material. In addition, insulative liner material may substantially continuously extend over and substantially cover side surfaces of the conductive material of the first conductive contact structure 114a and the second conductive contact structure 114b. The insulative liner material may be horizontally interposed between the conductive material of the first conductive contact structure 114a and the second conductive contact structure 114b and the conductive structures 108 of the tiers 110 of the stack structure 104, and may electrically isolate the conductive material from the conductive structures 108 of the tiers 110 of the stack structure 104. In some embodiments, the conductive material of the first conductive contact structure 114a and the second conductive contact structure 114b is formed of and includes W, and the insulative liner material is formed of and includes at least one dielectric oxide material (e.g., SiOₓ, such as SiO₂).

In some embodiments, one or more of the first conductive contact structure 114a and the second conductive contact structure 114b vertically extend from one or more conductive structures other than the conductive routing 112. For example, the first conductive contact structure 114a and/or the second conductive contact structure 114b may vertically extend from a conductive structure vertically overlying or vertically underlying the conductive routing 112. The first conductive contact structure 114a and the second conductive contact structure 114b may vertically extend from different conductive material tiers vertically overlying or vertically underlying the stack structure 104 so long as the first conductive contact structure 114a and the second conductive contact structure 114b are in electrical communication with each other (e.g., using one or more additional conductive contact structures).

The first conductive contact structure 114a and the second conductive contact structure 114b may individually comprise a single (e.g., only one), monolithic structure vertically extending at least partially through the memory array region 128; or may individually comprise a series of connected structures vertically extending at least partially through the memory array region 128. For example, the first conductive contact structure 114a may comprise a plurality (e.g., multiple) of conductive contact structures, where each of the plurality of conductive contact structures may be at a different vertical elevation (e.g., vertical position) than each other of the of the plurality of conductive contact structures. Furthermore, two or more of the plurality of conductive contact structures may be coupled to one another by way of one or more intervening conductive interconnect structures material (e.g., portions of conductive material layers) such that an electrical current provided to the plurality of conductive structures will flow through each of the plurality of conductive contact structures and any interstitial conductive material layer disposed between and coupled to two or more of the plurality of conductive contact structures.

Still referring to FIGS. 1, 2A, and 2B, the conductive loop structure 102 may include any number of additional material layers and/or conductive contact structures positioned between the material layers to form a loop structure. For example, additional conductive contact structures may vertically extend between the bond pad 118b and the first portion 134 of the first material 132 and between the bond pad 122b and the second portion 136 of the first material 132 if the first material 132 is disposed such that the first material 132 does not directly vertically underlie and horizontally overlap each of the bond pad 118b and the bond pad 122b.

Referring to FIGS. 2A and 2B, the conductive loop structure 102 may include contacts A and B, where contact A and/or contact B may be coupled to one or more devices or routing structures of the control logic region 130. For example, a device providing an electrical current may be coupled to the contact A to provide an electrical current to the conductive loop structure 102. The current may then exit through contact B via one or more routing structures of the control logic region 130, which may be coupled to another device or element of the microelectronic device 100.

Thus, a microelectronic device according to embodiments of the disclosure includes a memory array region, a control logic region, and an interconnect region. The memory array region includes a stack structure including tiers each including conductive material and insulative material vertically neighboring the conductive material. The memory array region also includes conductive routing overlying the stack structure. The interconnect region underlies the memory array region and include connected bond pads. The control logic region underlies the interconnect region and includes control logic devices to effectuate control operations for the microelectronic device. The microelectronic device also includes a conductive loop assembly extending, in a looped path, through each of the memory array region, the interconnect region, and the control logic region.

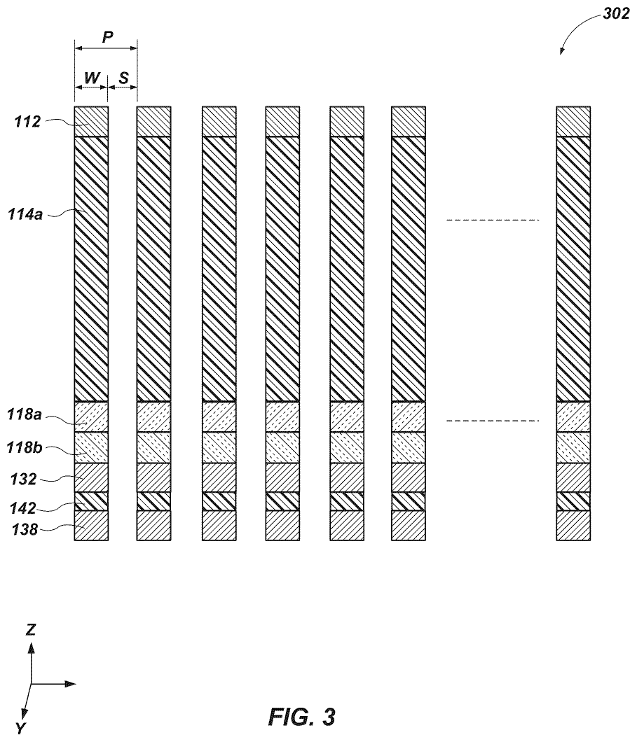

In some embodiments, the microelectronic device 100 includes a plurality of serially connected conductive loop structures 102 arranged as a conductive loop structure array. For example, FIG. 3 shows a simplified, vertical cross-sectional view of a conductive loop structure array 302 having a plurality of conductive loop structures 102 arranged in series, according to embodiments of the disclosure. As shown in FIG. 3, the microelectronic device 100 may include an array of conductive loop structure 102 arranged serially and substantially on a same axis (e.g., extending in the X-direction), where each conductive loop structure 102 in the array may be positioned with at least substantially equal spacing with regards to a next and/or previous conductive loop structure 102 in the array. For example, each conductive loop structure 102 may have a width (w) and be spaced a distance(s) from a next and/or previous conductive loop structure 102 in the series, such that a pitch (p) of for the conductive loop structures 102 of the conductive loop structure array 302 is substantially uniform (wherein w+s=p), as shown in FIG. 3. In some embodiments, w may be within a range of values from about 100 nm to about 200 nm, s may be within a range of values from about 100 nm to about 200 nm, and P may be within a range of values from about 200 nm to about 400 nm. Furthermore, the microelectronic device 100 may have any number of conductive loop structures 102 arranged in a series with one another.

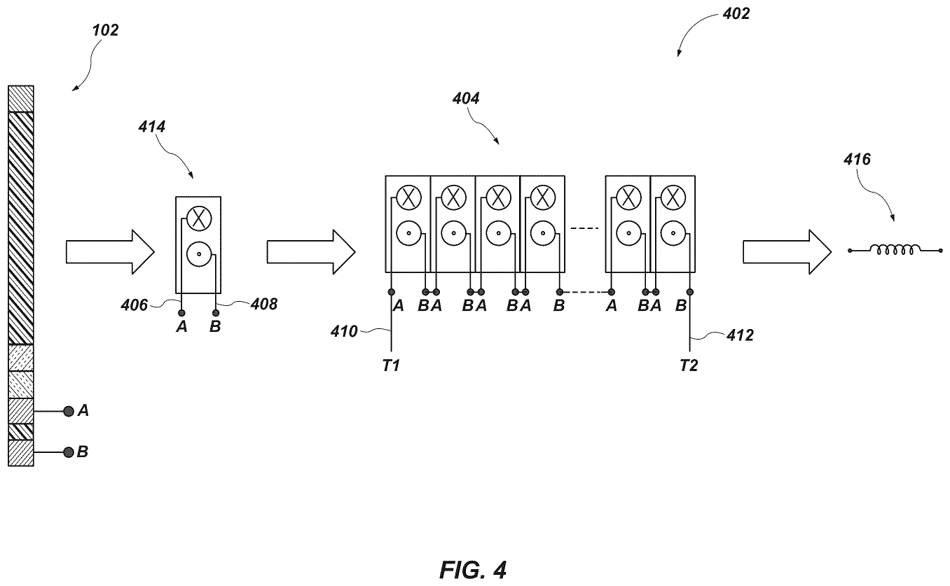

FIG. 4 shows a connection diagram illustrating connections for a wiring pattern for each conductive loop structure 102 of the conductive loop structure array 302 described with reference to FIG. 3 to form an inductive coil structure 416 (also referred to herein as an “inductor coil assembly” or an “inductor assembly”) responsive to an electrical current being provided to each conductive loop structure 102 in the conductive loop structure array 302, according to embodiments of the disclosure.

Referring to FIGS. 1-4 together, the symbol diagram 414 may represent a single conductive loop structure 102 and electrical contacts thereon and the diagram 404 may represent an array of conductive loop structures 102 such as the conductive loop structure array 402. Electrical contacts A and B of each conductive loop structure 102 may be coupled with various conductive routing structures (e.g., one or more conductive materials and/or conductive contact structures) of the control logic region 130. For example, a conductive routing structure 406 of the control logic region 130 configured to provide an electrical current may be coupled with the electrical contact A to provide an electrical current to conductive loop structure 102 at electrical contact A. Furthermore, another conductive routing structure 408 of the control logic region 130 may be coupled to electrical contact B such that the electrical current provided to electrical contact A flows through the conductive loop structure 102 to the electrical contact B and to the conductive routing structure 408 coupled to the electrical contact B. Furthermore, the conductive routing structure 408 coupled to electrical contact B may be coupled to an electrical contact A of a subsequent conductive loop structures 102 in the conductive loop structure array 302, such that the electrical current flowing from contact B of a conductive loop structure 102 may be provided, via the conductive routing structures 408 to contact A of a serially subsequent conductive loop structure 102 to form a conductive loop structure chain 404. This configuration may then be repeated for each conductive loop structure 102 of the conductive loop structure array 302.

A first conductive loop structure 102 of the conductive loop structure array 302 (e.g., a first conductive loop structure 102 to receive an electrical current relative to each other conductive loop structure 102 of the conductive loop structure array 302) may have its electrical contact A coupled to an electrical source structure 410 configured to provide an electrical current to contact A of the first conductive loop structure 102 of the conductive loop structure array 302. Furthermore, a last conductive loop structure 102 of the conductive loop structure array 302 (e.g., a last conductive loop structure 102 to receive an electrical current relative to each other conductive loop structure 102 of the conductive loop structure array 302) may have its electrical contact B connected, via conductive line 412, to another component of the microelectronic device 100 or to an electrical ground element. By connecting the conductive loop structure array 302 in this way, by providing an electrical current to the conductive loop structure array 302 such that the electrical current travels in a same direction in each conductive loop structure 102 of the conductive loop structure array 302, the conductive loop structure array 302 may act as an induction coil such that a magnetic flux providing magnetic force in a direction at least substantially perpendicular to the electrical current through the conductive loop structure array 302 (e.g., in the X-direction) may be generated responsive to applying an electric current to the conductive loop structure array 302.

Thus, a microelectronic device according to embodiments of the disclosure includes a memory array structure and a control logic structure. The memory array structure includes a stack structure comprising a vertically alternative sequence of conductive material and insulative material arranged in tiers. The memory array region also includes conductive routing vertically overlying the stack structures, conductive contact structures coupled to the first conductive routing and vertically extending completely through the stack structure, and bond pads coupled to the conductive contact structures. The control logic structure is bonded to the memory array structure and includes additional bond pads coupled to the bond pads of the memory array structure and additional conductive routing vertically underlying and coupled to the additional bond pads. The microelectronic device also includes an inductor assembly coiling through each of the memory array structure and the control logic structure, the inductor assembly including at least some of each of the conductive routing, the conductive contact structures, the bond pads, the additional bond pads, and the additional conductive routing.

Again, referring to FIGS. 1-4, the conductive loop structure array 302 may allow the microelectronic device 100 to leverage the magnetic flux generated by providing an electrical current to the conductive loop structure array 302 to generate an inductive coil-like structure within the microelectronic device 100. For example, by having this additional magnetic flux, certain operations of the microelectronic device 100 (e.g., read, write, erase operations) that require voltage may be performed using less power than conventional techniques, which may typically require charge pumps in order to obtain the necessary voltage. Additionally, the additional magnetic flux may also reduce a rise time of internal capacitance to reach a pre-determined operating voltage, which may also improve read, write, and erase operations of the microelectronic device 100. Furthermore, by circumventing the need for charge pumps, the microelectronic device 100 is able to use area that would typically be required for the charge pumps for other devices or interconnections that may increase performance, capacity, or reduce power consumption relative to conventional configurations of microelectronic devices including memory cells.

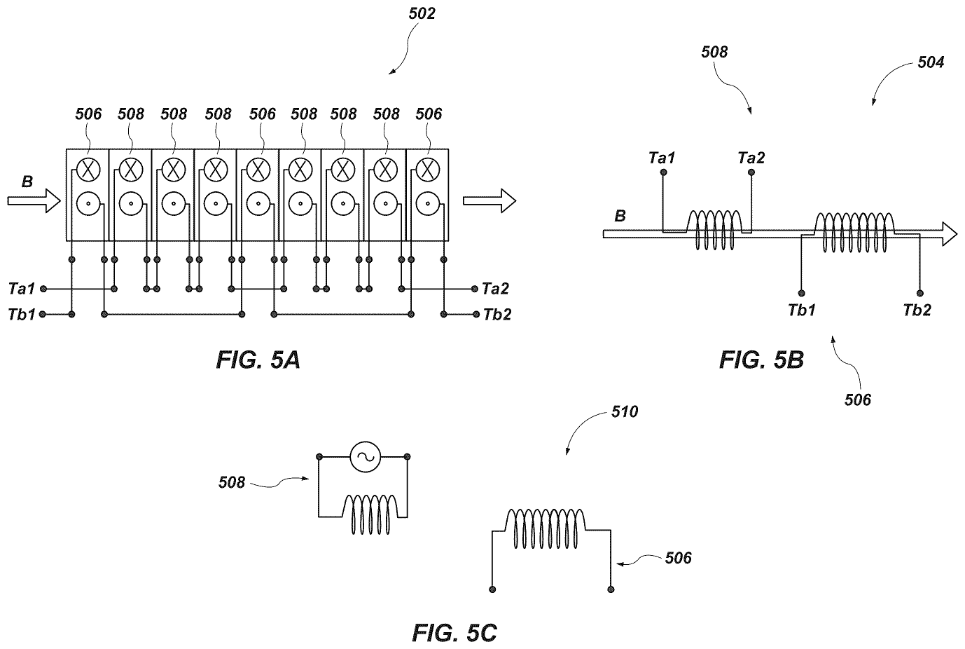

FIG. 5A shows an a connection diagram for an interleaved conductive loop structure array 502 that includes a first set of conductive loop structures 508 interleaved between a second set of conductive loop structures 506, according to embodiments of the disclosure. The first set of conductive loop structures 508 may be separately connected (e.g., connected to a different electrical current source or load) than the second set of conductive loop structures 506. As shown in FIG. 5, the first set of conductive loop structures 508 are connected to connections Ta1 and Ta2 and the second set of conductive loop structures 506 are connected to separate connections Tb1 and Tb2.

In some embodiments, the interleaved conductive loop structure array 502 is used to concatenate the magnetic flux B generated by the first set of conductive loop structures 508 with the magnetic flux B generated by the second set of conductive loop structures 506. FIG. 5B shows a diagram 504 demonstrating a magnetic flux generated by N1 loops (i.e., N1 conductive loop structures) of the first set of conductive loop structures 508 being combined with a magnetic flux generated by N2 loops of the second set of conductive loop structures 506. For example, the resulting concatenated magnetic flux may be calculated as follows:

$$M = \frac{μ \cdot N 1 \cdot N 2 \cdot S}{L} ,$$

wherein M is magnetic flux, u is a constant representative a magnetic permeability of a material affected by the magnetic flux generated by the first set of conductive loop structures 508 and the second set of conductive loop structures 506, N1 is the quantity of N1 loops, N2 is the quantity of N2 loops, S is the area of a section of a conductive loop structure defined by d×h as shown in FIG. 2A, and L is a length of conductive loop structure array defined by N×p as shown in FIG. 3.

In some embodiments, the interleaved conductive loop structure array 502 is used as a transformer. For example, a power source providing an electrical current to the first set of conductive loop structures 508 via Ta1 may cause a magnetic flux to be generated. The resulting magnetic flux may then induce a voltage in the second set of conductive loop structures 506 to provide a voltage to structures on a separate circuit compared to the first set of conductive loop structures 508. In some embodiments, a number of conductive loop structures in the first set of conductive loop structures 508 may be different than a number of conductive loop structures in the second set of conductive loop structures 506. FIG. 5C shows a transformer diagram 510 illustrating the use the first set of conductive loop structures 508 to induce a voltage E in the second set of conductive loop structures 506.

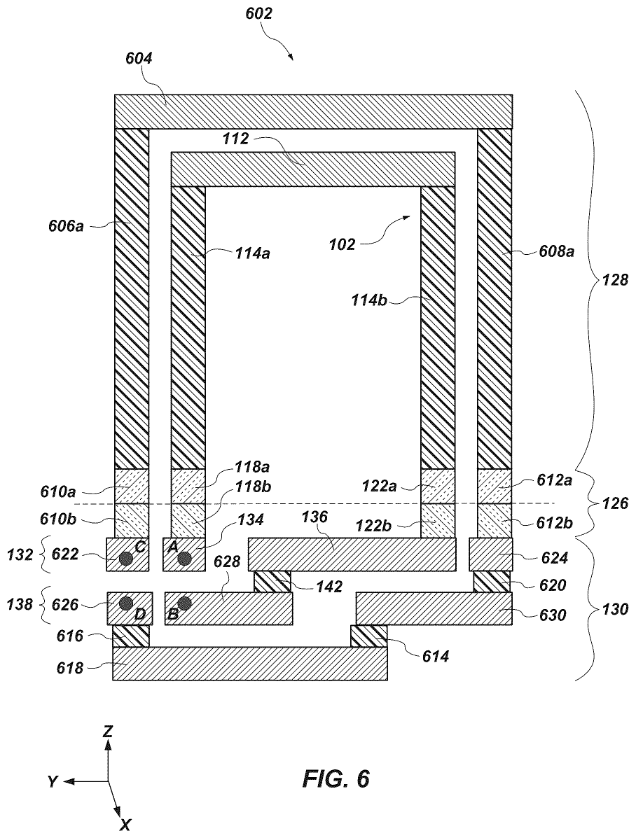

In some embodiments, the microelectronic device 100 include two or more concentric conductive loop structures. For example, FIG. 6 shows simplified, vertical side view of a configuration including an outer conductive loop structure 602 (also referred to herein as an “outer conductive loop assembly”) at least partially concentrically surrounding the conductive loop structure 102, according to embodiments of the disclosure. Referring to both FIG. 1 and FIG. 6 together, the outer conductive loop structure 602 may include additional conductive routing 604, a fourth conductive contact structure 606a, a fifth conductive contact structure 608a, bond pads 610a, 610b, 612a, 612b, a third portion 622 of the first material 132, a fourth portion 624 of the first material 132, a sixth conductive contact structure 620, a second portion 630 of the second material 138, a seventh conductive contact structure 614, a third material 618 of the control logic region 130, an eighth conductive contact structure 616, and a third portion of the second material 138.

The additional conductive routing 604 may at least partially overlie the conductive routing 112. The fourth conductive contact structure 606a and the fifth conductive contact structure 608a may vertically extend from the additional conductive routing 604 through the memory array region 128 of the microelectronic device 100 to the interconnect region 126. Specifically, the fourth conductive contact structure 606a may vertically extend to and be coupled to bond pads 610a and 610b, and is thereby coupled to the third portion 622 of the first material 132 of the control logic region 130. Moreover, the sixth conductive contact structure 620 vertically extends and is coupled to the bond pads 612a and 612b, and is thereby coupled to the third portion 622 of the first material 132 of the control logic region 130. Each of the first portion 134, second portion 136, third portion 622, and fourth portion 624 of the first material 132 may be separated (e.g., by insulative material) within the first material 132 such that an electrical current applied to one portion will not be conducted within the first material 132 to other portions of the first material 132.

The sixth conductive contact structure 620 vertically extends from the fourth portion 624 of the first material 132 to a second portion of the second material 138. The second material 138 may include a first portion 628, a second portion 630, and a third portion 626 that may be horizontally separated (e.g., by insulative material) from one another such that an electrical current applied to one portion of the second material 138 will not be directly conducted to other portions of the second material 138. The seventh conductive contact structure 614 may vertically extend from the second portion 630 of the second material 138 to the third material 618. The eighth conductive contact structure 616 may vertically extend from the third material 618 to the third portion 626 of the second material 138.

The first conductive contact structure 114a and the second conductive contact structure 114b may between the fourth conductive contact structure 606a and the fifth conductive contact structure 608a, such that the first conductive contact structure 114a and the second conductive contact structure 114b at least partially horizontally overlap (e.g., along the Y-direction) with the fourth conductive contact structure 606a and the fifth conductive contact structure 608a.

Still referring to FIG. 6, the outer conductive loop structure 602 may include additional conductive features (e.g., conductive materials and/or conductive structures) positioned between material tiers to form a loop structure. For example, additional conductive contact structures may vertically extend between the bond pad 610b and the third portion 622 of the first material 132 and between the bond pad 612b and the fourth portion 624 of the first material 132 if the first material 132 is disposed such that the first material 132 is not directly vertically below the bond pad 610b and/or the bond pad 612b. Furthermore, in some embodiments the fourth conductive contact structure 606a and the fifth conductive contact structure 608a vertically extend from a conductive structure other than the additional conductive routing 604. For example, the fourth conductive contact structure 606a and/or the fifth conductive contact structure 608a may vertically extend from a conductive structure overlying or underlaying at least part of the additional conductive routing 604. In some embodiments, the fourth conductive contact structure 606a and the second conductive contact structure 114b each extend from a different conductive material tier (e.g., including the additional conductive routing 604 or one or more material tiers overlying or underlying the additional conductive routing 604). In some embodiments, insulative material is disposed between the conductive loop structure 102 and the outer conductive loop structure 602.

The outer conductive loop structure 602 may include contacts C and D, where contact C and/or contact D may be electrically connected to one or more devices of the control logic region 130. For example, a device providing electrical power may be coupled (e.g., directly or via one or more routing structures of the control logic region 130) to the contact C to provide an electrical current to the outer conductive loop structure 602. The current may then go through the outer conductive loop structure 602 to and exit through contact D, which may be connected to another device or one or more routing structures of the control logic region 130.

In some embodiments, the microelectronic device 100 includes an array of serially connected outer conductive loop structures, wherein each outer conductive loop structure 602 of the array concentrically surrounds one or more conductive structures 108 of the conductive loop structure array 302. For example, contacts C and D may be coupled with various conductive routing structures (e.g., one or more material layers and/or conductive contact structures) of the control logic region 130. For example, a conductive routing structure of the control logic region 130 may be configured to provide an electrical current to contact C to provide an electrical current to an outer conductive loop structure 602 of the array of serially connected outer conductive loop structures. Furthermore, a conductive routing structure of the control logic region 130 may be coupled to contact D such that the electrical current applied to contact A flows through the outer conductive loop structure 602 to the contact D and to the conductive routing structure coupled to contact D. Furthermore, the routing structure coupled to contact D may be coupled to a contact C of a subsequent outer conductive loop structure 602 in the outer conductive loop structure array such that the electrical current flowing from contact D may be provided to contact C of a serially subsequent outer conductive loop structure 602. This configuration may be repeated for any number of serially subsequent outer conductive loop structures 602 of the outer conductive loop structure array.

By providing an electrical current separately to both the conductive loop structure 102 and the outer conductive loop structure 602, a magnetic flux may be generated at and/or around a center of the conductive loop structure 102 and the outer conductive loop structure 602, where the magnetic flux of each of the conductive loop structure 102 and the outer conductive loop structure 602 is concatenated to form a greater magnetic flux than a magnetic flux generated by the conductive loop structure 102 or the outer conductive loop structure 602 individually.

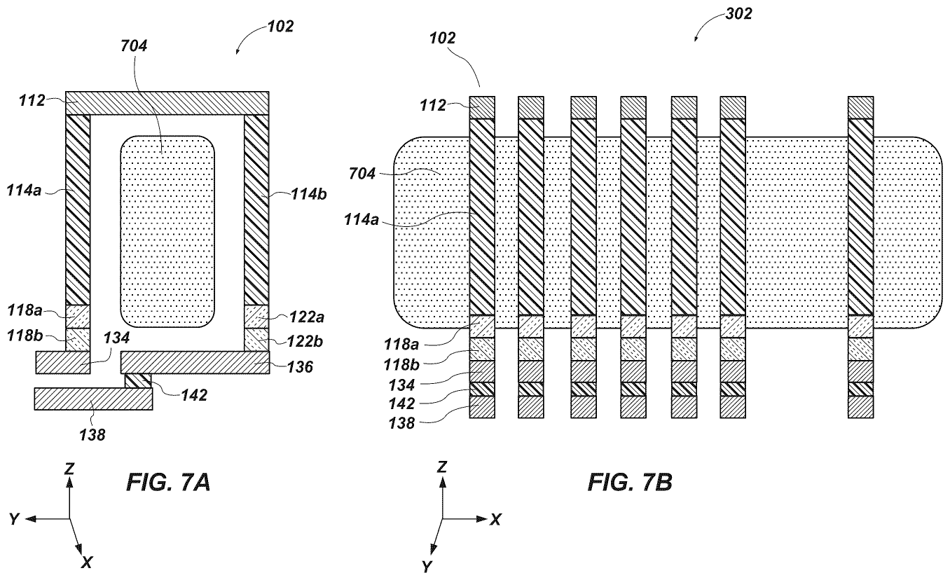

In some embodiments, the microelectronic device 100 of FIG. 1 include a ferromagnetic material disposed such that one or more conductive loop structures 102 may at least partially surround the ferromagnetic material. For example, FIGS. 7A and 7B show different simplified vertical side views, in directions orthogonal to one another, of the conductive loop structure 102 (FIG. 7A) and the conductive loop structure array 302 (FIG. 7B) previously described herein surrounding a ferromagnetic material, according to embodiments of the disclosure.

Referring collectively to FIGS. 7A and 7B, upon receiving an electrical current, the conductive loop structure array 302 may cause a magnetic flux to be created flowing generally in at least the X-direction within each conductive loop structure 102 of the conductive loop structure array 302. The inclusion of the ferromagnetic material may allow for increased magnetic field strength to focus the magnetic flux within and around the conductive loop structure array 302. Furthermore, the ferromagnetic material 704 may facilitate improved inductance to increase the performance of the conductive loop structure array 302 to provide increased voltage to various components of the microelectronic device 100. Furthermore, the ferromagnetic material 704 may reduce magnetic losses by guiding the magnetic flux more efficiently.

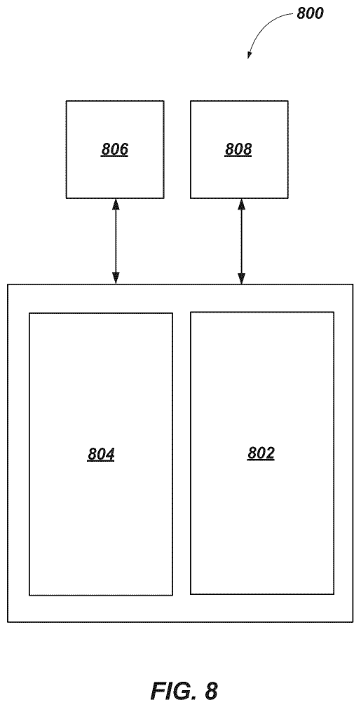

Microelectronic devices (e.g., the microelectronic device 100 (FIG. 1)) in accordance with embodiments of the disclosure may be used in embodiments of electronic systems of the disclosure. For example, FIG. 8 is a schematic block diagram of an illustrative electronic system according to embodiments of disclosure. The electronic system 800 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 800 includes at least one memory device 802. The memory device 802 may include, for example, a microelectronic device (e.g., the microelectronic device 100 (FIG. 1)) previously described herein. The electronic system 800 may further include at least one electronic signal processor device 804 (often referred to as a “microprocessor”). The electronic signal processor device 804 may, optionally, comprise a microelectronic device (e.g., the microelectronic device 100 (FIG. 1)) previously described herein. While the memory device 802 and the electronic signal processor device 804 are depicted as two (2) separate devices in FIG. 8, in additional embodiments, a single (e.g., only one) memory/processor device having the functionalities of the memory device 802 and the electronic signal processor device 804 is included in the electronic system 800. In such embodiments, the memory/processor device may include a microelectronic device (e.g., the microelectronic device 100 (FIG. 1)) previously described herein. The electronic system 800 may further include one or more input devices 806 for inputting information into the electronic system 800 by a user, such as, for example, a mouse or other pointing device, a keyboard, a touchpad, a button, or a control panel. The electronic system 800 may further include one or more output devices 808 for outputting information (e.g., visual or audio output) to a user such as, for example, a monitor, a display, a printer, an audio output jack, and/or a speaker. In some embodiments, the input device 806 and the output device 808 comprise a single touchscreen device that can be used both to input information to the electronic system 800 and to output visual information to a user. The input device 806 and the output device 808 may communicate electrically with one or more of the memory device 802 and the electronic signal processor device 804.

Thus, an electronic system according to embodiments of the disclosure includes an input device, an output device, a processor device operably coupled to the input device and the output device, and a memory device operably coupled to the processor device. The memory device includes conductive loop structures arranged in a series, each conductive loop structure of the series coupled to at least one other conductive loop structure of the series and having an at least substantially consistent orientation and positioned along a same axis relative to others of the conductive loop structures, the conductive loop structures respectively including a first conductive contact structure vertically extending from a first conductive routing structure, through tiers respectively comprising conductive material vertical adjacent insulative material, and to a first connected bond pad structure underlying the tiers, a second conductive contact structure horizontal offset from the first conductive contact structure and vertically extending from the first conductive routing structure, through the tiers, and to a second connected bond pad structure underlying the tiers, a second conductive routing structure vertically underlying and coupled to the first connected bond pad structure, and at least one third conductive routing structure vertically underlying and coupled to the second connected bond pad structure.

Thus, an electronic system according to embodiments of the disclosure includes an input device, an output device, a processor device operably coupled to the input device and the output device, and a memory device operably coupled to the processor device. The memory device includes a plurality of conductive loop structures arranged in a series, each conductive loop structure coupled to a previous and/or subsequent conductive loop structure in the series and having an at least substantially consistent orientation and positioned along a same axis relative to others of the plurality of conductive loop structures. Each conductive loop structure includes a first conductive contract structure vertically extending from a source structure of the one or more source structures through a memory array region of the microelectronic device to a first conductive bond pad of an interconnect region underlying the memory array region, the first conductive bond pad coupled to a first portion of a first material layer of a control logic region underlying the interconnect region, a second conductive contact structure vertically extending from the source structure through the memory array region to a second conductive bond pad of the interconnect region, the second conductive bond pad coupled to a second portion of the first material layer of the control logic region, and a third conductive contract structure vertically extending from the second portion of the first material layer to a second material layer at least partially underlying the first portion of the first material layer.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure.

What is claimed is:

1. A microelectronic device, comprising:
a memory array region comprising:
a stack structure comprising tiers each including conductive material and insulative material vertically neighboring the conductive material; and
conductive routing overlying the stack structure;
an interconnect region underlying the memory array region and comprising connected bond pads;
a control logic region underlying the interconnect region and comprising control logic devices configured to effectuate control operations for the microelectronic device; and
a conductive loop assembly extending, in a looped path, through each of the memory array region, the interconnect region, and the control logic region.

2. The microelectronic device of claim 1, wherein the conductive loop assembly comprises two or more conductive contact structures respectively vertically extending from the conductive routing of the memory array region to one of the connected bond pads of the interconnect region, the two or more conductive contact structures comprising:
a first conductive contact structure coupled to a first conductive material of the control logic region; and
a second conductive contact structure coupled to a second conductive material of the control logic region at least partially vertically underlying the first conductive material.

3. The microelectronic device of claim 2, wherein:
the first conductive contact structure vertically extends to a first of the connected bond pads of the interconnect region in electrical connection with a first portion of the first conductive material of the control logic region;
the second conductive contact structure vertically extends to a second of the connected bond pads of the interconnect region in electrical connection with a second portion of the first conductive material; and
insulative material disposed between and separates the first portion and the second portion of the first conductive material.

4. The microelectronic device of claim 3, wherein the conductive loop assembly further comprises a third conductive contact structure vertically extending from the second portion of the first conductive material to a first portion of the second conductive material.

5. The microelectronic device of claim 4, wherein:
the first portion of the first conductive material includes a first electrical contact at an end thereof; and
the first portion of the second conductive material includes a second electrical contact at an additional end thereof, the first electrical contact at least partially overlying the second electrical contact.

6. The microelectronic device of claim 5, wherein the control logic region further comprises:
additional conductive routing coupled to the first electrical contact; and
further conductive routing coupled to the second electrical contact.

7. The microelectronic device of claim 4, further comprising an additional conductive loop assembly extending, in an additional looped path, through each of the memory array region, the interconnect region, and the control logic region, the additional conductive loop assembly at least partially concentrically surrounding and electrically insulated from the conductive loop assembly.

8. The microelectronic device of claim 7, wherein the additional conductive loop assembly comprises:
an additional conductive routing conductive routing of the memory array region;
a fourth conductive contact structure extending from the additional conductive routing to a third of the connected bond pads of the interconnect region, the third of the connected bond pads electrically connected to a third portion of the first conductive material;
a fifth conductive contact structure extending from the additional conductive routing to a fourth of the connected bond pads of the interconnect region, the fourth of the connected bond pads electrically connected to a fourth portion of the first conductive material;
a sixth conductive contact structure vertically extending from the fourth portion of the first conductive material to a second portion of the second conductive material;
a seventh conductive contact structure vertically extending from the second portion of the second conductive material to a third conductive material at least partially underlying the second conductive material; and
an eighth conductive contact structure vertically extending from the third conductive material to a third portion of the second conductive material.

9. The microelectronic device of claim 8, wherein the first conductive contact structure and the second conductive contact structure are at least partially horizontally between the fourth conductive contact structure and the fifth conductive contact structure.

10. The microelectronic device of claim 2, wherein the two or more conductive contact structures comprise conductively filled vias within a horizontal area of and vertically extending completely through the stack structure of the memory array region.

11. A microelectronic device, comprising:
a memory array structure comprising:
a stack structure comprising a vertically alternative sequence of conductive material and insulative material arranged in tiers;
conductive routing vertically overlying the stack structures;
conductive contact structures coupled to a first conductive routing and vertically extending completely through the stack structure; and
bond pads coupled to the conductive contact structures; and
a control logic structure bonded to the memory array structure and comprising:
additional bond pads coupled to the bond pads of the memory array structure; and
additional conductive routing vertically underlying and coupled to the additional bond pads; and
an inductor assembly coiling through each of the memory array structure and the control logic structure, the inductor assembly comprising at least some of each of the conductive routing, the conductive contact structures, the bond pads, the additional bond pads, and the additional conductive routing.

12. The microelectronic device of claim 11, further comprising a ferromagnetic material horizontally and vertically circumscribed by the inductor assembly.

13. The microelectronic device of claim 11, wherein the inductor assembly comprises:
a first set of conductive loop structures connected to a first electrical circuit and coiling through the memory array structure and the control logic structure; and
a second set of conductive loop structures connected to a second electrical circuit and coiling through the memory array structure and the control logic structure.

14. The microelectronic device of claim 13, wherein the conductive loop structures of the first set of conductive loop structures are interleaved between the conductive loop structures of the second set of conductive loop structures.

15. The microelectronic device of claim 13, wherein the first set of conductive loop structures are configured to provide at least some voltage to the second set of conductive loop structures responsive to an electrical current being applied to the first set of conductive loop structures.

16. The microelectronic device of claim 11, wherein at least a portion of the stack structure is horizontally and vertically circumscribed by the inductor assembly.

17. The microelectronic device of claim 11, wherein inductor assembly comprises conductive loop structures coupled to one another in series, each of the conductive loop structures comprising:
a portion of the conductive routing of the memory array structure;
two of the conductive contact structures of the memory array structure coupled to the portion of the conductive routing of the memory array structure;
two of the bond pads of the memory array structure coupled to the two of the conductive contact structures of the memory array structure;
two of the additional bond pads of the control logic structure coupled to the two of the bond pads of the memory array structure; and
a portion of the additional conductive routing of the control logic structure coupled to the two of the additional bond pads of the control logic structure.

18. An electronic system comprising:
an input device;
an output device;
a processor device operably coupled to the input device and the output device; and
a memory device operably coupled to the processor device and comprising:
conductive loop structures arranged in a series, each conductive loop structure of the series coupled to at least one other conductive loop structure of the series and having an at least substantially consistent orientation and positioned along a same axis relative to others of the conductive loop structures, the conductive loop structures respectively comprising:
a first conductive contact structure vertically extending from a first conductive routing structure, through tiers respectively comprising conductive material vertical adjacent insulative material, and to a first connected bond pad structure underlying the tiers;
a second conductive contact structure horizontal offset from the first conductive contact structure and vertically extending from the first conductive routing structure, through the tiers, and to a second connected bond pad structure underlying the tiers;
a second conductive routing structure vertically underlying and coupled to the first connected bond pad structure; and
at least one third conductive routing structure vertically underlying and coupled to the second connected bond pad structure.

19. The electronic system of claim 18, wherein the at least one third conductive routing structure comprises two third conductive routing structures, one of the two third conductive routing structures at a vertical elevation of the second conductive routing structure, and an other of the two third conductive routing structures coupled to and vertically underlying the one of the two third conductive routing structures.

20. The electronic system of claim 19, wherein the other of the two third conductive routing structures at least partially horizontally overlaps the second conductive routing structure.
